(19) United States
(12) Patent Application Publication
(10) Pub. No.: US 2006/0148186 A1
(43) Pub. Date: Jul. 6, 2006

(54) Method and apparatus for manufacturing gallium nitride based single crystal substrate

(75) Inventors: Soo Min Lee, Seoul (KR); Masayoshi Koike, Suwon (KR); Kyeong Ik Min, Seoul (KR); Cheol Kyu Kim, Seoul (KR); Sung Hwan Jang, Yongin (KR); Min Ho Kim, Suwon (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: Samsung Electro-Mechanics Co., Ltd., Suwon (KR)

(21) Appl. No.: 11/220,020

(22) Filed: Sep. 6, 2005

(30) Foreign Application Priority Data
Jan. 3, 2005 (KR) 10-2005-0000265

(51) Int. Cl. H01L 21/336

(52) U.S. Cl. 438/308

(57) ABSTRACT

A method and apparatus for manufacturing a nitride based single crystal substrate. The method includes placing a preliminary substrate on a susceptor installed in a reaction chamber; growing a nitride single crystal layer on the preliminary substrate; and irradiating a laser beam to separate the nitride single crystal layer from the preliminary substrate under the condition that the preliminary substrate is placed in the reaction chamber.

### RELATED APPLICATION

The present invention is based on, and claims priority from, Korean Application Number 2005-000265, filed Jan. 3, 2005, the disclosure of which is incorporated by reference herein in its entirety.

### BACKGROUND OF THE INVENTION

1. Field of the Invention

The present invention relates to a method and apparatus for manufacturing a nitride based single crystal substrate, and a method and apparatus for manufacturing a nitride based single crystal substrate, in which the reduction of yield caused due to cracks generated by a laser lift off process is relieved.

2. Description of the Related Art

Recently, a semiconductor element emitting light at a low wavelength band has been developed in a new-generation illumination field as well as an optical disk field requiring high-density and high-resolution in recording/reproducing data. A nitride based single crystal substrate made of GaN is widely used to form the semiconductor element emitting light at this low wavelength band. For example, a gallium nitride (GaN) single crystal has an energy band gap of 3.39 eV, thus being proper to emit blue light having a low wavelength band.

Generally, the gallium nitride single crystal is manufactured by vapor growth, such as metal organic chemical vapor deposition (MOCVD) or hydride vapor phase epitaxy (HVPE), or molecular beam epitaxy (MBE). Here, a sapphire (α-Al₂O₃) substrate or a Sic substrate is used as a substrate made of a material differing from GaN. For example, since a difference of lattice constants between sapphire and gallium nitride is approximately 13% and a difference of thermal expansion coefficients between sapphire and gallium nitride is −34%, stress is generated from an interface between the sapphire substrate and the gallium nitride single crystal, thereby causing lattice defects and cracks in the crystal. Theses defects and cracks cause a difficulty in growing a high-quality nitride crystal, thus decreasing reliability of a semiconductor element manufactured from the gallium nitride single crystal and shortening the life time of the semiconductor element.

In order to solve the above problem, a technique, in which a nitride based semiconductor element is grown directly on a nitride based single crystal substrate, has been proposed. Here, a freestanding nitride based single crystal substrate is required.

Such a freestanding nitride based single crystal substrate is obtained by growing a nitride single crystal bulk on a preliminary substrate, such as a sapphire substrate, and removing the preliminary substrate from the nitride single crystal bulk. Here, a laser lift off process is used to remove the sapphire substrate from the nitride single crystal bulk.

In the laser lift off process, a laser beam is irradiated so that the sapphire substrate from a GaN based single crystal bulk by decomposing the GaN based single crystal bulk into gallium (Ga) and nitride (½N₂) on an interface between the sapphire substrate and the GaN based single crystal bulk.

When a crystal having a small thickness is grown on a wafer having a small diameter of less than 2 inches, the conventional laser lift off process is applied without causing chemical deformation or cracks. However, since the preliminary substrate is made of material differing from the nitride single crystal, when the wafer has a diameter of more than 2 inches or a crystal having a designated thickness or more is grown on the wafer, as shown in FIG. 1, the preliminary substrate and the crystal are severely warped and cracks (C) are generated from the interface therebetween due to a difference of lattice constants between the preliminary substrate and the GaN based single crystal bulk and a difference of thermal expansion coefficients between the preliminary substrate and the GaN based single crystal bulk.

Particularly, thermal stress caused by the difference of thermal expansion coefficients generates an excessive concentration of the nitride crystal, which is grown at a high temperature (900˜1,200° C.), in a cooling step at a normal temperature for performing the laser lift off process.

Accordingly, a method for manufacturing a high-quality nitride based single crystal substrate, which prevents the generation of stress between a nitride single crystal bulk and a growth substrate, such as a sapphire substrate, and more particularly, solves a stress problem caused by a difference of thermal expansion coefficients between the nitride single crystal bulk and the growth substrate, and an apparatus using the same have been required.

### SUMMARY OF THE INVENTION

Therefore, the present invention has been made in view of the above problems, and it is an object of the present invention to provide a method for manufacturing a nitride based single crystal substrate, in which a laser lift off process is continuously performed in a chamber maintained at the same temperature when or after a nitride single crystal is grown on a preliminary substrate, such as a sapphire substrate or a SiC substrate, thereby preventing the generation of stress due to a difference of thermal expansion coefficients between the nitride single crystal and the preliminary substrate.

It is another object of the present invention to provide an apparatus for manufacturing a nitride based single crystal substrate, which is properly used by the above method.

In accordance with one aspect of the present invention, the above and other objects can be accomplished by the provision of a method for manufacturing a nitride based single crystal substrate comprising: placing a preliminary substrate on a susceptor installed in a reaction chamber; growing a nitride single crystal layer on the preliminary substrate; and irradiating a laser beam to separate the nitride single crystal layer from the preliminary substrate under the condition that the preliminary substrate is placed in the reaction chamber.

Preferably, the irradiation of the laser beam may be performed in-situ, thus being performed at a temperature in the range of 800˜1,200° C., in which the nitride single crystal layer is grown. More preferably, the irradiation of the laser beam may be performed at substantially the same temperature as a temperature at which the nitride single crystal layer is grown. Thereby, it is possible to minimize the generation of stress due to a difference of thermal expansion coefficients between the nitride single crystal layer and the preliminary substrate, thus preventing cracks or warpage of the substrate and the nitride single crystal layer caused in the irradiation of the laser beam.

The nitride single crystal layer may be a single crystal layer satisfying the composition of AlₓIn_{y}Ga_{1-x-y}N (Here, 0≦x≦1, 0≦y≦1, and 0≦x+y≦1. The preliminary substrate may be made of one selected from the group consisting of sapphire, SiC, Si, MgAl₂O₄, MgO, LiAlO₂, and LiGaO₂.

When the preliminary substrate is a silicon substrate, preferably, in order to decrease a difference of lattice constants between the preliminary substrate and the nitride single crystal layer, the method may further comprise growing a low-temperature buffer layer satisfying the composition of AlₓIn_{y}Ga_{1-x-y}N (Here, 0≦x≦1, 0≦y≦1, and 0≦x+y≦1) on the preliminary substrate before the growth of the nitride single crystal layer.

Preferably, a transparent window for irradiating the laser beam onto the preliminary substrate placed on the susceptor may be formed through an upper surface the reaction chamber.

In this case, when the preliminary substrate is made of a material, such as sapphire, having an energy band gap wider than that of the nitride single crystal layer, the irradiation of the laser beam includes: moving the preliminary substrate so that the laser beam is irradiated onto a lower surface of the preliminary substrate on which the nitride single crystal layer is formed; and irradiating the laser beam onto the lower surface of the preliminary substrate.

When the preliminary substrate is made of a material, such as silicon, having an energy band gap narrower than that of the nitride single crystal layer, the irradiation of the laser beam includes irradiating the laser beam onto the nitride single crystal layer formed on an upper surface of the preliminary substrate.

Preferably, the growth of the nitride single crystal layer may include: first growing the nitride single crystal film having a designated thickness; and secondarily growing nitride single crystal on the first-grown the nitride single crystal film; and the irradiation of the laser beam may be performed between the first growth and the second growth.

Alternately, preferably, the method may further comprise irradiating the laser beam between the first growth and the second growth for partially separating the nitride single crystal layer from the preliminary substrate, and the irradiation of the laser beam for completely separating the nitride single crystal layer from the preliminary substrate may be performed after the second growth.

The irradiation of the laser beam employed between the first growth and the second growth relieves the generation of stress caused by a difference of lattice constants between the preliminary substrate and the nitride single crystal layer. That is, in order to relieve the generation of stress increased according to the increase in the thickness of the grown nitride single crystal layer, the laser beam is irradiated so as to partially or completely separate the nitride single crystal layer from the preliminary substrate after the nitride single crystal film having a designated thickness is first grown, thereby minimizing stress generated during the second growth of the nitride single crystal.

In the case that the irradiation of the laser beam for partially or completely separating the nitride single crystal layer from the preliminary substrate is employed between the first growth of the nitride single crystal film and the second growth of the nitride single crystal, when the preliminary substrate is a silicon substrate, preferably, the thickness of the first-grown nitride single crystal film may be 0.1 ˜1 μm.

On the other hand, when the preliminary substrate is a sapphire substrate, preferably, the thickness of the first-grown nitride single crystal film may be 5˜100 μm.

In the irradiation of the laser beam for partially separating the nitride single crystal layer from the preliminary substrate, the laser beam may be irradiated such that laser beam irradiation regions are separated from each other by a designated interval.

The growth of the nitride single crystal layer may be performed by hydride vapor phase epitaxy (HVPE), metal organic chemical vapor deposition (MOCVD), or molecular beam epitaxy (MBE).

In accordance with another aspect of the present invention, there is provided an apparatus for manufacturing a nitride single crystal layer comprising: a reaction chamber for growing a nitride single crystal therein; a susceptor installed in the reaction chamber for fixing a preliminary substrate; and a transparent window formed through an upper surface of the reaction chamber for irradiating a laser beam onto an upper surface of the preliminary substrate fixed to the susceptor.

In accordance with the present invention, the irradiation of the laser beam for separating the nitride single crystal layer from the preliminary substrate is performed in the reaction chamber in which the growth of the nitride single crystal layer is performed, thereby minimizing the generation of stress due to a difference of thermal expansion coefficients between the nitride single crystal layer and the preliminary substrate. The preliminary substrate is made of sapphire, SiC, Si, MgAl₂O₄, MgO, LiAlO₂, and LiGaO₂. The direction of the irradiation of the laser beam varies according to the energy band gap of the preliminary substrate. For example, the preliminary substrate is made of a material, such as sapphire, having an energy band gap wider than that of the nitride single crystal layer, a laser beam having a middle wavelength (for example, 266 nm or 355 nm) is irradiated onto a lower surface of the preliminary substrate. On the other hand, when the preliminary substrate is made of a material, such as silicon, having an energy band gap narrower than that of the nitride single crystal layer, a laser beam having a middle wavelength (for example, 532 nm or 1,064 nm) is irradiated onto an upper surface of the nitride single crystal layer.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view illustrating a step of separating a nitride single crystal from a sapphire substrate;

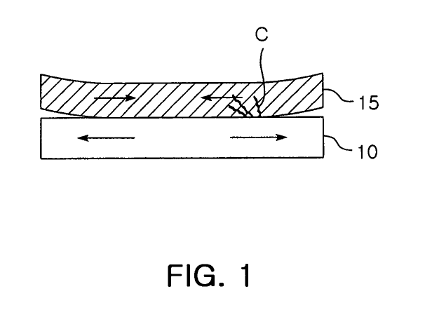

FIGS. 2A to 2D are sectional views illustrating a method for manufacturing a nitride based single crystal substrate in accordance with one embodiment of the present invention;

FIGS. 3A to 3D are sectional views illustrating a method for manufacturing a nitride based single crystal substrate in accordance with another embodiment of the present invention;

FIGS. 4A and 4B are schematic views illustrating laser beam irradiation traces employed by the present invention;

FIGS. 5A to 5E are sectional views illustrating a method for manufacturing a nitride based single crystal substrate in accordance with yet another embodiment of the present invention; and

FIGS. 6A and 6B are sectional views of apparatuses for manufacturing a nitride based single crystal substrate of the present invention.

### DESCRIPTION OF THE PREFERRED EMBODIMENTS

Now, preferred embodiments of the present invention will be described in detail with reference to the annexed drawings.

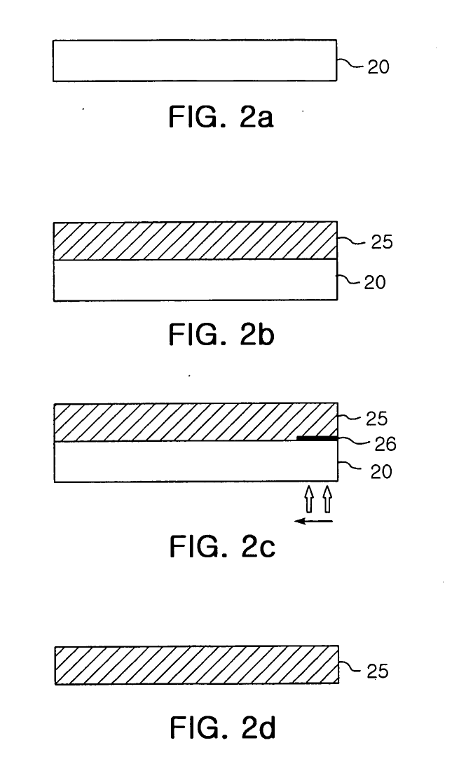

FIGS. 2A to 2D are sectional views illustrating a method for manufacturing a nitride based single crystal substrate in accordance with one embodiment of the present invention. In this embodiment, a sapphire substrate having an energy band gap larger than that of a nitride single crystal layer to be grown is used.

As shown in FIG. 2A, the method of this embodiment of the present invention begins with preparation of a sapphire substrate 20 serving as a preliminary substrate. The sapphire substrate 20 is placed in a reaction chamber for performing HVPE, MOCVD, or MBE. In order to grow a high-quality nitride single crystal on the sapphire substrate 20, a buffer layer (not shown) may be formed in advance on the sapphire substrate 20 at a low temperature (less than 900° C.).

Thereafter, as shown in FIG. 2B, a nitride single crystal layer 25 is grown on the sapphire substrate 20. The nitride single crystal layer 25 satisfies the composition of AlₓIn_{y}Ga_{1-x-y}N (Here, 0≦x≦1, 0≦y≦1, and 0≦x+y≦1). The nitride single crystal layer 25 is grown by HVPE, MOCVD, or MBE, but requires a high temperature of 800˜1,200° C. Here, the thickness of the grown nitride single crystal layer 25 is more than 400 μm.

As shown in FIG. 2C, a laser beam is continuously irradiated onto the lower surface of the sapphire substrate 20 in the reaction chamber. Since the laser beam irradiation is performed in-situ, i.e., in the reaction chamber, it is possible to minimize a variation in temperature inducing thermal stress. The laser beam irradiation is performed preferably at a temperature of 800˜1,200° C., and more preferably at the same temperature as the temperature for growing the nitride single crystal layer 25. When the laser beam is irradiated onto the lower surface of the sapphire substrate 20, the nitride single crystal layer 25 is decomposed into nitrogen gas and a V-group metal 26. For example, when a GaN based single crystal layer is grown on the sapphire substrate 20, the GaN based single crystal layer is decomposed into nitrogen gas and Ga under the condition that nitrogen gas and Ga are separable.

Then, an interface between the nitride single crystal layer 25 and the sapphire substrate 20 is converted into the V-group metal 26 by irradiating the laser beam over the entire surface of the sapphire substrate 20. Thereafter, as shown in FIG. 2D, the nitride single crystal layer 25 is separated from the sapphire substrate 20 by melting the obtained V-group metal 26.

The separation of the nitride single crystal layer from the sapphire substrate by irradiating the laser beam in accordance with this embodiment is accomplished by preparing a transparent window formed through an upper portion of the reaction chamber for irradiating the laser beam towards the upper surface of the nitride single crystal layer and by moving the sapphire substrate using a substrate position adjusting arm so that the laser beam is irradiated onto the lower surface of the sapphire substrate provided with the nitride single crystal layer formed thereon.

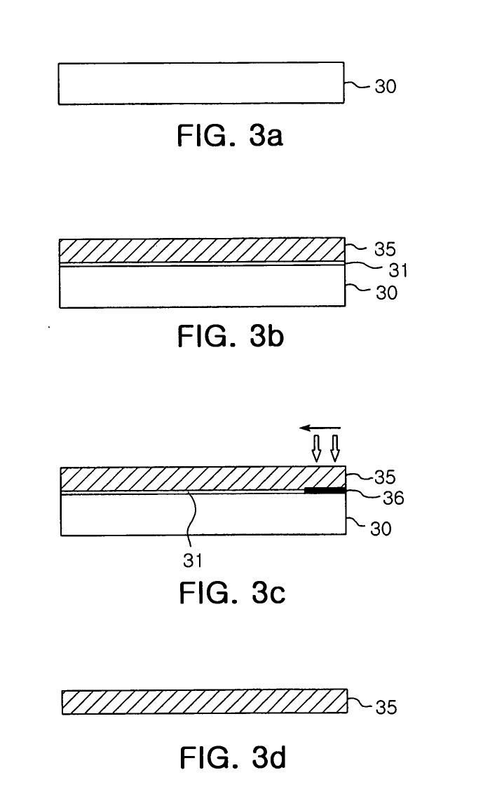

The present invention may provide a method for manufacturing a nitride based single crystal substrate, which uses a preliminary substrate having a band gap smaller than the energy band gap of the nitride single crystal layer. FIGS. 3A to 3D are sectional views illustrating a method for manufacturing a nitride based single crystal substrate, in which a silicon substrate is used as the preliminary substrate, in accordance with another embodiment of the present invention.

As shown in FIG. 3A, the method of this embodiment of the present invention begins with placement of a silicon substrate 30 in a reaction chamber. Thereafter, as shown in FIG. 3B, a buffer layer 31 is formed on the silicon substrate 30, and then a nitride single crystal layer 35 is grown on the buffer layer 31 of the silicon substrate 30. The buffer layer 31 is a low-temperature buffer layer satisfying the composition of AlₓIn_{y}Ga_{1-x-y}N (Here, 0≦x≦1, 0≦y≦1, and 0≦x+y≦1), and the nitride single crystal layer 35 is made of a single crystal satisfying the composition of AlₓIn_{y}Ga_{1-x-y}N (Here, 0≦x≦1, 0≦y≦1, and 0≦x+y≦1).

Thereafter, as shown in FIG. 3C, a laser beam is irradiated onto the upper surface of the silicon substrate 30 in the reaction chamber. Here, the laser beam is irradiated onto the upper surface of the nitride single crystal layer 35, thereby evaporating or melting silicon placed at an interface between the silicon substrate 30 and the nitride single crystal layer 35. Similar to the preceding embodiment, since the laser beam irradiation of this embodiment is performed in-situ, i.e., in the reaction chamber, it is possible to minimize a variation in temperature inducing thermal stress. The laser beam irradiation is performed preferably at a temperature of 800˜1,200° C., and more preferably at the same temperature as the temperature for growing the nitride single crystal layer 35.

Then, the silicon placed at the interface between the nitride single crystal layer 35 and the silicon substrate 30 is evaporated or melted by irradiating the laser beam over the entire surface of the silicon substrate 30. Thereby, as shown in FIG. 3D, the nitride single crystal layer 35 is separated from the silicon substrate 30.

The laser beam irradiation for separating the nitride single crystal layer from the preliminary substrate may be accomplished via various methods. For example, a laser beam irradiation trace has various shapes.

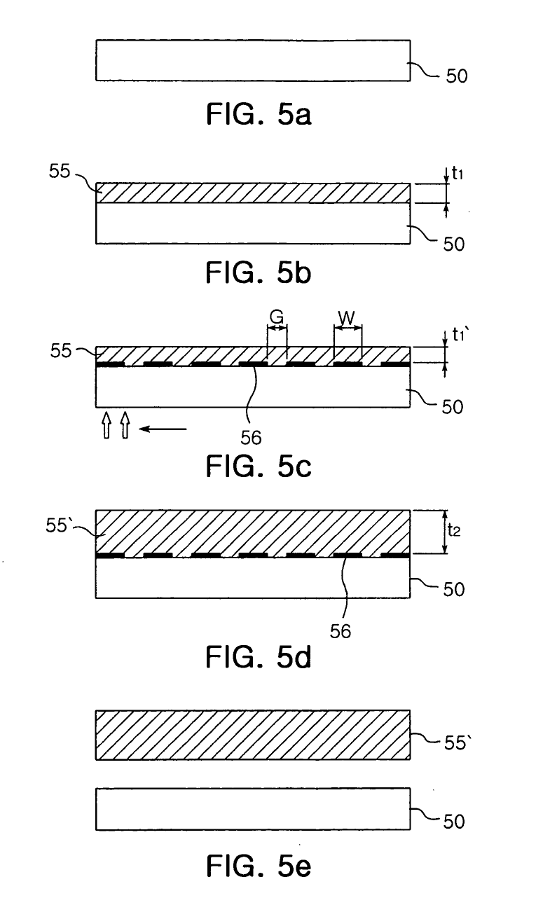

Further, although the above embodiment describes that the laser beam irradiation serves to completely separate the nitride single crystal layer from the preliminary substrate, the laser beam irradiation may serve to partially separate the nitride single crystal layer from the preliminary substrate by deforming the laser beam irradiation trace. Thereby, a more preferred embodiment, in which stress caused by a difference of lattice constants between the preliminary substrate and the nitride single crystal layer during the growth of the nitride single crystal layer is relieved, may be provided. Such an embodiment will be described in detail with reference to FIG. 5A to 5E.

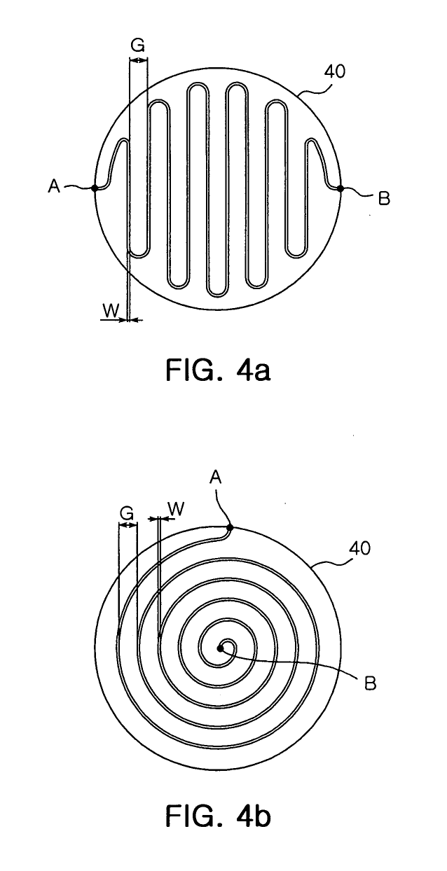

The present invention employs the laser beam irradiation, in which a laser beam is irradiated such that a laser beam irradiation trace starts at one edge point of a preliminary substrate and terminates at another edge point of the preliminary substrate. The start of the laser beam irradiation trace from the one edge point of the preliminary substrate facilitates the discharge of nitrogen generated when the nitride is decomposed. Thereby, two laser beam irradiation methods are proposed. Hereinafter, with reference to FIGS. 4A and 4B, two laser beam irradiation traces according to these methods will be described.

FIGS. 4A and 4B illustrate laser beam irradiation traces on a wafer 40 serving as a preliminary substrate.

First, as shown in FIG. 4A, a laser beam is irradiated over the entire surface of the wafer 40 such that a laser beam irradiation trace has a zigzag shape from one edge point of the wafer 40 to another edge point of the wafer 40. Differently from the above laser beam irradiation trace, as shown in FIG. 4B, the laser beam may be irradiated over the entire surface of the wafer 40 such that a laser beam irradiation trace has a spiral shape from one edge point of the wafer 40 to another internal point (for example, the central point) of the wafer 40.

Here, when the interval between neighboring trace lines having a designated line width (W) is expressed by G, the interval (G) is set to several tens or several hundreds of μm, thereby partially separating the nitride single crystal layer from the preliminary substrate. In consideration of resolution of the irradiated laser beam, the interval (G) is set to a value close to zero or less than zero (that is, the neighboring trace lines are overlapped with each other), thereby completely separating the nitride single crystal layer from the preliminary substrate.

FIGS. 5A to 5E are sectional views illustrating a method for manufacturing a nitride based single crystal substrate in accordance with yet another embodiment of the present invention.

As shown in FIG. 5A, the method of this embodiment of the present invention begins with placement of a sapphire substrate 50 serving as a preliminary substrate in a reaction chamber for performing HVPE, MOCVD, or MBE. As described above, in order to grow a high-quality nitride single crystal on the sapphire substrate 50, a buffer layer (not shown) may be formed in advance on the sapphire substrate 50 at a low temperature (less than 900° C.).

Thereafter, as shown in FIG. 5B, a nitride single crystal film 55 having a designated thickness (t1) is first grown on the sapphire substrate 50. The nitride single crystal film 55 is made of a single crystal satisfying the composition of AlₓIn_{y}Ga_{1-x-y}N (Here, 0≦x≦1, 0≦y≦1, and 0≦x+y≦1). Preferably, the first-grown nitride single crystal film 55 has a thickness of 5˜100 μm. When the thickness of the first-grown nitride single crystal film 55 is not more than 5 μm, the generation of stress due to a difference of lattice constants between the sapphire substrate 50 and the first-grown nitride single crystal film 55 is excessively low, and when the thickness of the first-grown nitride single crystal film 55 is not less than 100 μm, the generation of stress is severe. Accordingly, the above range of the thickness of the first-grown nitride single crystal film 55 is proper.

Thereafter, as shown in FIG. 5C, a laser beam is continuously irradiated onto the lower surface of the sapphire substrate 50 in the reaction chamber. The laser beam irradiation is performed in the reaction chamber, thereby not generating thermal stress. In this embodiment, a partial separation step is performed and an III-group metal region is formed on a partial area of the interface between the nitride single crystal film 55 and the sapphire substrate 50 so that the nitride single crystal film 55 is partially separated from the sapphire substrate 50. Thereby, the stress generated due to a difference of lattice constants between the sapphire substrate 50 and the nitride single crystal film 55 is relieved. Further, the thickness of the high-quality nitride single crystal layer is increased by an additional nitride growth step. The partial separation step is easily performed by setting the interval (G) between the trace lines to a value larger than zero, and preferably several tens or several hundreds of μm, as described in FIGS. 4A and 4B.

Thereafter, as shown in FIG. 5D, the additional nitride growth step is performed, thereby forming a nitride single crystal layer 55′ having a larger thickness (t2) under the condition that the effect of stress is minimized. As described above, the nitride growth is achieved by the first and second nitride growth steps, and the laser irradiation step is performed between the first and second nitride growth steps, thereby enabling formation of the nitride single crystal layer 55′ having a thickness of more than approximately 400 μm.

Finally, as shown in FIG. 5E, the laser beam is additionally irradiated, thereby completely separating the nitride single crystal layer 55′ from the sapphire substrate 50. Preferably, in order to minimize thermal stress, the complete separation step is performed in the reaction chamber. However, since the thermal stress is reduced when the regions of the nitride single crystal film 55 partially separated from the sapphire substrate 50 are large, the complete separation step may be performed at the outside of the reaction chamber, i.e., at the normal temperature.

Although this embodiment describes the partial separation of the nitride single crystal layer from the sapphire substrate using the laser beam, the complete separation of the nitride single crystal layer from the sapphire substrate may be performed because the nitride single crystal layer first grown on the sapphire substrate has a thickness withstanding the impact of the laser beam.

Further, although, this embodiment uses the sapphire substrate as a preliminary substrate, a silicon substrate may be used. The silicon substrate is highly influenced by a difference of lattice constants between the preliminary substrate and the nitride single crystal layer more than the sapphire substrate. Accordingly, when the silicon substrate is used, preferably, the first-grown nitride single crystal layer has a thickness of 0.1˜1 μm. In this case, the nitride single crystal layer having a thickness of approximately 3˜4 μm may be grown on the silicon substrate through the partial separation of the first-grown nitride single crystal layer from the silicon substrate.

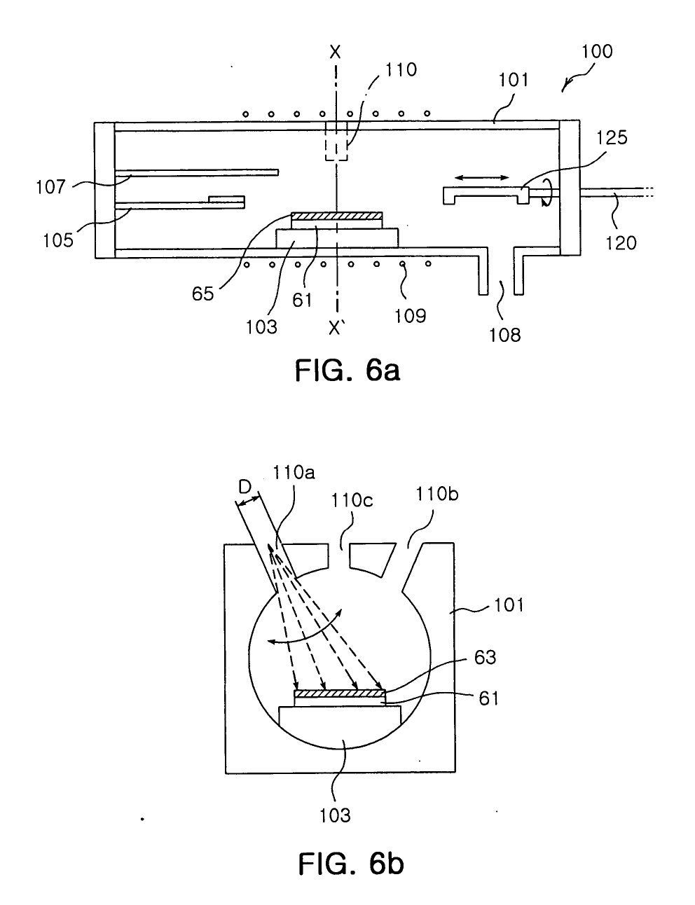

FIGS. 6A and 6B are sectional views of apparatuses for manufacturing a nitride based single crystal substrate of the present invention.

With reference to FIG. 6A, the apparatus 100 comprises a reaction chamber 101, in which a nitride single crystal is grown, a susceptor 103 installed in the reaction chamber 100 for fixing a preliminary substrate 61, and a transparent window 110, through which a laser beam is irradiated to the reaction chamber 101. The reaction chamber 101 is maintained at a high temperature by a heating unit 109, such as a coil. When a source for growing nitride is supplied from source gas supply units 105 and 107, a nitride single crystal layer 65 is grown on the preliminary substrate 61.

The transparent window 110 is formed through the upper surface of the reaction chamber 101 so that the laser beam is irradiated onto the upper surface of the preliminary substrate 61 to be fixed to the susceptor 103. The transparent window 110 has a diameter (D) sufficient to irradiate the laser beam onto the entire upper surface of the nitride single crystal layer 65. When the growth of the nitride is completed or is going on, the laser beam is supplied to the preliminary substrate 61 through the transparent window 110. Alternately, as shown in FIG. 6B, another apparatus 100 comprises several transparent windows. The transparent windows include a transparent window 110a for separating the nitride single crystal layer 65 from the preliminary substrate 61 by irradiating a laser beam, and a transparent window 110c: for measuring the thickness of the nitride single crystal layer 65 grown on the preliminary substrate 61. The transparent windows further include a transparent window 110b formed at a position opposite to the transparent window 110a. The transparent windows 110a and 110b are used as pots for measuring the warpage of the nitride single crystal layer 65.

When a sapphire substrate is used as the preliminary substrate 61, the apparatus 100 further comprises a substrate position adjusting arm 120 for moving the preliminary substrate 61 so that the laser beam is irradiated onto the lower surface of the preliminary substrate 61. The substrate position adjusting arm 120 is provided with a vacuum suction unit 125.

As apparent from the above description, the present invention provides a method and apparatus for manufacturing a nitride based single crystal substrate, in which the separation of a nitride single crystal layer from a preliminary substrate by irradiating a laser beam is continuously performed in a reaction chamber so that thermal stress is minimized, thereby growing a high-quality nitride single crystal layer in a high thickness. Further, the method and apparatus of the present invention employ the partial separation of the nitride single crystal layer from the preliminary substrate during the growth of the nitride single crystal layer, thereby relieving the generation of stress due to a difference of lattice constants between the nitride single crystal layer and the preliminary substrate, thus providing high-quality crystal growth conditions.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method for manufacturing a nitride based single crystal substrate comprising:
placing a preliminary substrate on a susceptor installed in a reaction chamber;
growing a nitride single crystal layer on the preliminary substrate; and
irradiating a laser beam to separate the nitride single crystal layer from the preliminary substrate under the condition that the preliminary substrate is placed in the reaction chamber.

2. The method as set forth in claim 1, wherein the irradiation of the laser beam is performed at a temperature in the range of 800˜1,200° C.

3. The method as set forth in claim 2, wherein the irradiation of the laser beam is performed at the same temperature as a temperature at which the nitride single crystal layer is grown.

4. The method as set forth in claim 1, wherein the nitride single crystal layer is a single crystal layer satisfying the composition of AlₓIn_{y}Ga_{1-x-y}N (Here, 0≦x≦1, 0≦y≦1, and 0≦x+y≦1).

5. The method as set forth in claim 1, wherein the preliminary substrate is made of one selected from the group consisting of sapphire, SiC, Si, MgAl₂O₄, MgO, LiAlO₂, and LiGaO₂.

6. The method as set forth in claim 1, further comprising growing a low-temperature buffer layer satisfying the composition of AlₓIn_{y}Ga_{1-x-y}N (Here, 0≦x≦1, 0≦y≦1, and 0≦x+y≦1) on the preliminary substrate before the growth of the nitride single crystal layer,
wherein the preliminary substrate is a silicon substrate.

7. The method as set forth in claim 1, wherein a transparent window for irradiating the laser beam onto the preliminary substrate placed on the susceptor is formed through an upper surface of the reaction chamber.

8. The method as set forth in claim 7, wherein:
the preliminary substrate is made of a material having an energy band gap wider than that of the nitride single crystal layer; and
the irradiation of the laser beam includes:
moving the preliminary substrate so that the laser beam is irradiated onto a lower surface of the preliminary substrate on which the nitride single crystal layer is formed; and
irradiating the laser beam onto the lower surface of the preliminary substrate.

9. The method as set forth in claim 1, wherein:
the preliminary substrate is made of a material having an energy band gap narrower than that of the nitride single crystal layer; and
the irradiation of the laser beam includes irradiating the laser beam onto the nitride single crystal layer formed on an upper surface of the preliminary substrate.

10. The method as set forth in claim 1, wherein:
the growth of the nitride single crystal layer includes:
first growing a nitride single crystal film having a designated thickness; and
secondarily growing a nitride single crystal on the first-grown the nitride single crystal film; and
the irradiation of the laser beam is performed between the first growth and the second growth.

11. The method as set forth in claim 1, wherein the growth of the nitride single crystal layer includes:
first growing a nitride single crystal film having a designated thickness; and
secondarily growing a nitride single crystal on the first-grown the nitride single crystal film,
further comprising irradiating the laser beam between the first growth and the second growth for partially separating the nitride single crystal layer from the preliminary substrate.

12. The method as set forth in claim 11, wherein:
the preliminary substrate is a silicon substrate; and
the thickness of the first-grown nitride single crystal film is 0.1˜μm.

13. The method as set forth in claim 11, wherein:
the preliminary substrate is a sapphire substrate; and
the thickness of the first-grown nitride single crystal film is 5˜100 μm.

14. The method as set forth in claim 11, wherein, in the irradiation of the laser beam for partially separating the nitride single crystal layer from the preliminary substrate, the laser beam is irradiated such that laser beam irradiation regions are separated from each other by a designated interval.

15. The method as set forth in claim 1, wherein the growth of the nitride single crystal layer is performed by hydride vapor phase epitaxy (HVPE), metal organic chemical vapor deposition (MOCVD), or molecular beam epitaxy (MBE).

16. An apparatus for manufacturing a nitride single crystal layer comprising:
a reaction chamber for growing a nitride single crystal therein;
a susceptor installed in the reaction chamber for fixing a preliminary substrate; and
a transparent window formed through an upper surface of the reaction chamber for irradiating a laser beam onto an upper surface of the preliminary substrate fixed to the susceptor.

17. The apparatus as set forth in claim 16, further comprising a substrate position adjusting arm for moving the preliminary substrate so that the laser beam is irradiated onto a lower surface of the preliminary substrate fixed to the susceptor.
